(19) United States
(12) Patent Application Publication
(10) Pub. No.: US 2021/0389663 A1
(43) Pub. Date: Dec. 16, 2021

(54) METHOD AND DEVICE FOR OPTICAL PROXIMITY EFFECT CORRECTION

(71) Applicant: CHANGXIN MEMORY TECHNOLOGIES, INC., Hefei City (CN)

(72) Inventor: CHIH-LI CHEN, Hefei (CN)

(73) Assignee: CHANGXIN MEMORY TECHNOLOGIES, INC., Hefei City (CN)

(21) Appl. No.: 17/461,547

(22) Filed: Aug. 30, 2021

Related U.S. Application Data
(63) Continuation of application No. PCT/CN2021/082461, filed on Mar. 23, 2021.

(30) Foreign Application Priority Data
Apr. 8, 2020 (CN) 202010271782.8

(51) Int. Cl. G03F 1/36; G06F 30/398

(52) U.S. Cl. CPC G03F 1/36; G06F 30/398

(57) ABSTRACT

The present disclosure discloses a method and a device for optical proximity effect correction, wherein the method for the optical proximity effect correction comprises: acquiring an original target pattern and preprocessing the original target pattern to form a secondary target pattern so that the secondary target pattern meets a preset processing rule: performing optical proximity effect correction on the secondary target pattern to acquire a corrected pattern; acquiring a simulated contour of the original target pattern based on the corrected pattern; calculating a deviation between the simulated contour and the original target pattern; and judging whether the corrected pattern meets the processing requirements based on the deviation value. The present disclosure provides the method and the device for optical proximity effect correction to solve the existing problem of serious distortion of photo-etched patterns after the optical proximity effect correction.

### CROSS-REFERENCE TO RELATED APPLICATIONS

This application is a continuation of International Patent Application No. PCT/CN2021/082461, which claims priority to Chinese Patent Application No. 202010271782.8, filed on Apr. 8, 2020. The above-referenced applications are incorporated herein by reference in their entirety.

### TECHNICAL FIELD

The present disclosure relates to the field of semiconductor technology, and in particular to a method and a device for optical proximity effect correction.

### BACKGROUND

With the downsizing and integration of integrated circuit components, the critical dimension of each film layer is getting smaller and smaller. In the process of semiconductor technology, a mask pattern is often transferred to a silicon wafer by photo-etching to form patterns of various film layers. However, the smaller the dimension of each component is, the lower the accuracy of photo-etching will be.

Specifically, during the process of photo-etching, due to the interference and diffraction effects of light, there is some distortion and deviation between the actual photo-etched pattern and the mask pattern on the silicon wafer, that is, an optical proximity effect (OPE). The OPE may cause a right-angle corner to be rounded and the width of the straight line of the photo-etched pattern to be widened or narrowed, and/or the like. In order to avoid distortion of the photo-etched pattern caused by OPE, an optical proximity correction (OPC) method is adopted in the prior art to modify the mask pattern in advance, so that the modified pattern is enabled to make up for defects caused by the OPE as much as possible, and then the modified mask pattern is transferred to the silicon wafer to generate a photo-etched pattern.

In practical applications, due to the diversification of the original target pattern, there are still differences between the photo-etched pattern and the original target pattern. And in some cases, there may be a problem that the contour of the photo-etched pattern cannot cover the target contour, which causes serious distortion of the photo-etched pattern. The main characteristics of the distortion are line width deviation, line shortening, missing patterns or strips, rounded corners or the like. The distortion of photo-etched pattern affects the performance of the device directly, thereby reducing the yield of production.

### SUMMARY

The disclosed embodiment provides a method and a device for optical proximity effect correction to solve the existing problem of serious distortion of photo-etched patterns after the optical proximity effect correction.

In a first aspect, the disclosed embodiment provides a method for optical proximity effect correction, the method including:

acquiring an original target pattern and preprocessing the original target pattern to form the secondary target pattern, so that the secondary target pattern meets a preset processing rule;

performing optical proximity effect correction on the secondary target pattern to acquire a corrected pattern;

acquiring a simulated contour of the original target pattern based on the corrected pattern;

calculating a deviation between the simulated contour and the original target pattern; and judging whether the corrected pattern meets the processing requirements based on a value of the deviation.

In a second aspect, the disclosed embodiment provides a device for optical proximity effect correction, which is configured to implement the method for optical proximity effect correction provided by any embodiment of the present disclosure, the device including:

a secondary processing module, configured to acquire an original target pattern and preprocess the original target pattern to form a secondary target pattern so that the secondary target pattern meets a preset processing rule;

a correcting module, configured to perform optical proximity effect correction on the secondary target pattern to acquire a corrected pattern;

a contour module, configured to acquire a simulated contour of the original target pattern based on the corrected pattern;

a deviation calculating module, configured to calculate a deviation between the simulated contour and the original target pattern; and

an iterating module, configured to call the correcting module and the contour module in a cyclical manner until the value of the deviation acquired by the deviation calculating module meets the processing requirements.

### BRIEF DESCRIPTION OF THE DRAWINGS

FIG. 1 is a flowchart of a method for optical proximity effect correction according to an embodiment of the present disclosure;

FIG. 2 is a flowchart of another method for optical proximity effect correction according to an embodiment of the present disclosure;

FIG. 3 is a structural diagram of an original target pattern according to an embodiment of the present disclosure;

FIG. 4 is a structural diagram of another original target pattern according to an embodiment of the present disclosure;

FIG. 5 is a structural diagram of a comparison between an original target pattern and a secondary target pattern according to an embodiment of the present disclosure;

FIG. 6 is a structural diagram of a comparison between another original target pattern and the secondary target pattern according to an embodiment of the present disclosure;

FIG. 7 is a structural diagram of a comparison between yet another original target pattern and the secondary target pattern according to an embodiment of the present disclosure;

FIG. 8 is a flowchart of another method for optical proximity effect correction according to an embodiment of the present disclosure;

FIG. 9 is a structural diagram of yet another original target pattern according to an embodiment of the present disclosure;

FIG. 10 is a structural diagram of lines in a target pattern according to an embodiment of the present disclosure;

FIG. 11 is a flowchart of another method for optical proximity effect correction according to an embodiment of the present disclosure;

FIG. 12 is a structural diagram of an optical auxiliary line according to an embodiment of the present disclosure;

FIG. 13 is a structural diagram of another optical auxiliary line according to an embodiment of the present disclosure;

FIG. 14 is a structural diagram of yet another optical auxiliary line according to an embodiment of the present disclosure; and

FIG. 15 is a structural diagram of a device for optical proximity effect correction according to an embodiment of the present disclosure.

### DESCRIPTION OF EMBODIMENTS

The present disclosure will be further described in detail in combination with the accompanying drawings and embodiments. It can be understood that the specific embodiments described herein are only used to explain the present disclosure, but not to limit the present disclosure. It should also be noted that for ease of description, only part of the structure relevant to this disclosure rather than the entire structure is shown in the accompanying drawings.

During the process of semiconductor technology, critical dimensions of critical film layers whose technical requirements are 0.18 microns or less such as an active zone layer, a gate oxide layer, and a metal connecting layer become increasingly smaller. Some critical dimensions have almost been set to be less than the wavelength of the light used in the photo-etching step. During the photo-etching step, pattern transfer is susceptible to the deviation due to the influence of light, that is, optical proximity effect. The factor that causes the optical proximity effect is that when the light beam passes through the mask pattern on the mask plate and is projected on the photoresist, on the one hand, the energy distribution and phase distribution of the intensity spectrum of the light beam are somewhat distorted relative to the ideal image spectrum, which is a diffraction effect, and on the other hand, the light beam passes through the photoresist and is then reflected by a semiconductor substrate of a chip, which causes interference. As a result, repeated exposures occur and change the actual exposure of the photoresist layer. Generally, an ideal pattern (target pattern) which needs to be formed on a film layer can be corrected by an optical proximity effect correction model to form a corrected pattern so that the exposed pattern (photo-etched pattern) formed on the film layer by the corrected pattern is close to the target pattern. However, some pattern settings in the target pattern cause serious distortion of the photo-etched pattern formed after the target pattern is corrected, which results in greater distortion. In this regard, the settings of the pattern that is prone to distortion is preprocessed in the present disclosed embodiments. The preset processing rule is set for the target pattern to be corrected so that the optical proximity effect correction is performed on the target pattern that meets the preset processing rules. Thus, the finally formed photo-etched pattern is closer to the original target pattern, thereby improving the accuracy of the photo-etched pattern.

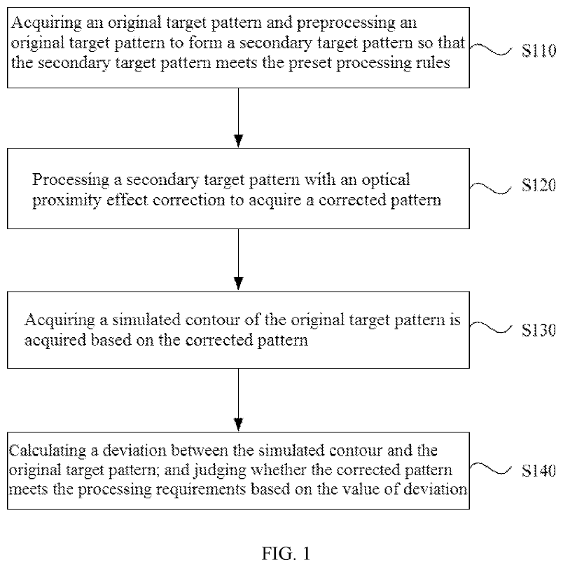

In particular, a method for optical proximity effect correction is provided in embodiments of the present disclosure. FIG. 1 is a flowchart of a method for optical proximity effect correction according to an embodiment of the present disclosure. As shown in FIG. 1, the method for optical proximity effect correction includes the following steps.

In step S110, an original target pattern is acquired and the original target pattern is preprocessed to form a secondary target pattern so that the secondary target pattern meets a preset processing rule.

The original target pattern includes a pattern which a user desires to form on a chip or a silicon wafer. In the present embodiment, a mask pattern on a mask plate is designed in advance so that a photo-etched pattern close to the original target pattern is formed on a photoresist layer after the photo-etching technology is applied to the mask pattern.

In order to prevent the photo-etched pattern eventually formed on the silicon wafer after the original target pattern is modified by the optical proximity effect model original target pattern from being distorted seriously, it is necessary to preprocess the original target image to remove the structural factors that cause the distortion of the photo-etched pattern. In some embodiments, if the distortion of the pattern is mainly a deviation in line width, the structure that caused the deviation in line width will be adjusted, deleted or filled. If the distortion of the pattern is mainly a connected stripe, the size and spacing of the target pattern are reset to an extent that the distortion of the photo-etched pattern will not be caused. In some embodiments, the preset processing rules are set based on a relationship between the distortion and the target pattern, and the parts in the original target pattern that do not meet the preset processing rules are adjusted and processed to acquire the secondary target pattern. After the secondary target pattern is processed by the optical proximity effect correction, a structure susceptible to distortion is avoided to a great extent. It should be understood that the preprocessing of the original target pattern includes checking the original target pattern against the preset processing rules, and preprocessing the checked original target patterns that do not meet the preset process rules.

In step S120, a secondary target pattern is processed with an optical proximity effect correction to acquire a corrected pattern.

In some embodiments, the target layout pattern can be corrected by a correction model to acquire a corrected pattern. For example, optical proximity correction models include optical models and resist models. In the optical proximity correction process, the optical model is used at first. The optical model above is utilized to simulate the spatial light intensity distribution on the surface of silicon wafer after diffraction of the exposed beam through the lens group with the exposed beam irradiating the mask pattern. Next, a photoresist model is used. The photoresist model is utilized to simulate the light intensity distribution of the surface of the silicon wafer being on the photoresist. Portions of the photoresist that are above a certain exposure threshold undergo a chemical reaction and are denatured, thereby being dissolved in the developing solution. In the present embodiment, the photoresist model is a constant threshold photoresist model, that is, the photoresist exposure reference threshold is fixed. Compared with the variable threshold photoresist model, a simplified photoresist model can avoid the complexity of acquiring the optical proximity correction model caused by a complex photoresist model.

In step S130, a simulated contour of the original target pattern is acquired based on the corrected pattern.

The process of the mask exposure is simulated with the corrected pattern to acquire the simulated contour. The simulated contour is the simulated exposed pattern or photo-etched pattern. Although the simulated contour is not exactly the same as the original target pattern and there is an error therebetween, the present embodiment enables the simulated contour to further fit the original target pattern to improve the effect of the optical proximity effect correction.

In step S140, a deviation value between the simulated contour and the original target pattern is calculated; and whether the corrected pattern meets the processing requirements is judged based on the value of the deviation.

If the deviation between the simulated contour and the original target pattern meets the processing requirements, it means that the effect of the optical proximity effect correction is qualified. The mask pattern can be formed based on the corrected pattern. The accuracy of the photo-etched pattern formed by the exposure of the mask pattern is high and close to that of the original target pattern, which improves the accuracy of correction and quality of the mask.

In some embodiments, the method for optical proximity effect correction may further include: performing optical proximity effect correction on the secondary target pattern multiple times until the value of the deviation between the acquired simulated contour and the original target pattern meets the processing requirements.

In some embodiments, it is possible that the final corrected pattern cannot be acquired directly after a process of the optical proximity effect correction. In most cases, it is necessary to perform optical proximity correction multiple times to acquire a more accurate corrected pattern to form a mask pattern. Therefore, steps S120 to S140 need be executed multiple times to acquire the final corrected pattern. However, in the present embodiment, the original target pattern is preprocessed to form the secondary target pattern so that the formed simulated contour becomes close to the original target pattern more quickly after the optical proximity effect correction is performed on the secondary target pattern, which reduces the number of cycles from step S120 to step S140, reduces the number of calling the optical proximity effect correction model, accelerates the process of the optical proximity effect correction, and improves the accuracy of correction.

In the present embodiment, prior to the optical proximity effect correction is performed on the target pattern, the original target pattern is preprocessed. To be specific, the original target pattern that will affect the accuracy of the exposed pattern finally exposed on the film layer is corrected and adjusted in advance to form the second target pattern. That is, the original target pattern that does not meet the preset processing rules is adjusted to form the second target pattern that meets the preset processing rules, the optical proximity effect correction is performed on the secondary target pattern to acquire a corrected pattern, and an exposure process is simulated on the corrected pattern to acquire a simulated contour. The simulated contour is compared with the original target pattern and may be determined as the accurate final corrected pattern if the deviation value meets the processing requirements, and an exposed pattern which is close to the original target pattern is acquired based on the corrected pattern. Compared with direct optical proximity effect correction on the original target pattern, processing the original target pattern in advance eliminates factors which cause deformation to the final simulated contour, ensures that the simulated contour is close to the original target pattern, prevents serious distortion of the exposed pattern, improves the performance of the device which is formed finally, and increases the yield of production.

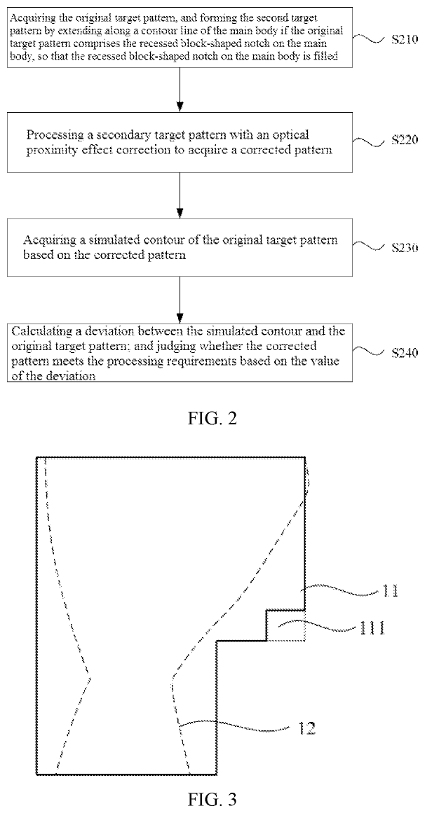

In some embodiments, the preset processing rules may include that a main body does not include a recessed block-shaped notch. Accordingly, the process of preprocessing the original target pattern is specifically limited by the embodiments of the present disclosure. As shown in FIG. 2, which is a flowchart of another method for optical proximity effect correction according to an embodiment of the present disclosure, the method for the optical proximity effect correction includes the following step.

In step S210, the original target pattern is acquired. If the original target pattern comprises the recessed block-shaped notch on the main body, the second target pattern is formed by extending along a contour line of the main body so that the recessed block-shaped notch on the main body is filled.

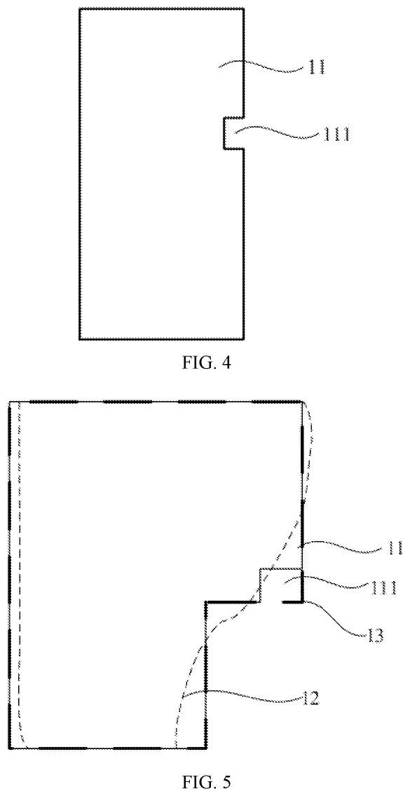

Generally, the target patterns are irregular patterns, such as an elongated object projecting from the main body and a recessed slit in the main body. In some embodiments, the preset processing rules may include that a main body does not include a recessed block-shaped notch. FIG. 3 is a structural diagram of an original target pattern according to an embodiment of the present disclosure. FIG. 4 is a structural diagram of yet another original target pattern according to an embodiment of the present disclosure. As shown in FIG. 3 and FIG. 4, the original pattern may include a recessed block-shaped notch 111 in the main body 11. If the optical proximity effect correction is performed directly on the original target pattern, the block-shaped notch 111 will greatly affect the accuracy of the final simulated contour, thus causing distortion of the simulated contour. As shown in FIG. 3, the contour formed by the dashed line in FIG. 3 is the simulated contour 12. It can be known that the structure of the block-shaped notch 111 makes the distortion rate of the original target pattern increase through the optical proximity effect correction model. The basic main body 11 cannot be covered by the simulated contours 12 so that the simulated contour may be corrected several times by the optical proximity effect correction model to gradually perfect the shape of the simulated contour. It is easy to cause the entire process of optical proximity effect correction to be more complicated and prolong the cycle. Moreover, the accuracy of the finally formed mask pattern is not high enough. In the present embodiment, the original target pattern may be preprocessed at first to eliminate the recessed block-shaped notch 111 in the main body and form a secondary target pattern, as shown in FIG. 5, which is a structural diagram of a comparison between an original target pattern and a secondary target pattern according to an embodiment of the present disclosure. The secondary target pattern 13 can be formed by extending along the contour line of the main body 11. As shown in FIG. 5, the recessed block-shaped notch 111 on the original target pattern is filled to form the secondary target pattern 13. After the secondary target pattern 13 is corrected by the optical proximity effect correction model, a simulated contour 12 is formed. As the deviation between the simulated contour 12 and the original target object is small, a qualified mask pattern can be acquired after the simulated contour 12 is corrected a few times by the optical proximity effect correction model.

Based on the aforementioned embodiment, reference is made to FIG. 5. If the block-shaped notch 111 is formed at a corner or a turn, the step S210 is performed, that is, if the original target pattern includes a recessed block-shaped notch in the main body, the secondary target pattern is formed by extending along a contour line of the main body so that the recessed block-shaped notch in the main body is filled, which includes: if the original target pattern includes a recessed block-shaped notch formed in the corner area of two mutually perpendicular contour lines of the main body, the corner area is filled along the contour line of the main body to form a right-angle area and the secondary target pattern is formed. If the change of the block notch 111 which acts as an important position limit at the corner or turn has a great influence on the simulated contour 12, the block-shaped notch 111 at the corner or turn is filled according to the present embodiment so that the block-shaped notch 111 at the corner or turn forms a right-angle area and a secondary target pattern 13 is thus formed. The secondary target pattern 13 makes the simulated contour 12 closer to the original target pattern to improve the accuracy of correction.

In some embodiments, the minimum size of the block-shaped notch 11 is less than or equal to 10 nm. When the minimum size of the block-shaped notch 111 is less than or equal to 10 nm, the influence on the distortion of the simulated contour 12 is greater. As a result, when the minimum size of the block-shaped notch 111 is less than or equal to 10 nm, the block-shaped notch 111 can be filled or repaired. When the block-shaped notch 111 is greater than 10 nm, the influence on the simulated contour 12 is less. The block-shaped notch 111 can be processed as a normal main body.

The recessed block-shaped notch 111 in the main body shown in FIGS. 4 and 5 is rectangular. It is certain that the block-shaped notch 111 may also have other shapes in a specific embodiment in the present embodiment, as shown in FIG. 6, which is a structural diagram of a comparison between another original target pattern and the secondary target pattern according to an embodiment of the present disclosure. The recessed block-shaped notch 111 may further include several notch units 111a arranged in a stepped manner. Accordingly, the main body 11 includes a stepped structure 112 corresponding to the notch unit 111a in a one-to-one relationship. Accordingly, if the original target pattern includes a recesses block-shaped notch 111 on the main body 11, the block-shaped notch 111 is extended along the contour line of the main body 11 to form the secondary target pattern 13, so that the block-shaped notch 111 recessed in the main body 11 is filled, which includes: if the block-shaped notch 111 of the original target pattern includes multiple notch units 111a arranged in a stepped manner, the notch units 111a are filled, and/or, a stepped structure 112 corresponding to the notch units 111a is removed to form a secondary target pattern 13 so that the minimum dimension of the recessed block-shaped notch is larger than 10 nm.

As shown in FIG. 6, when the block-shaped notch 111 of the original target pattern includes multiple notch units 111a, it is possible that the whole block-shaped notch 111 cannot be directly filled. According to the present embodiment, the numbers of the notch units 111a corresponding to the block-shaped notches 111 and the stepped structures 112 on the main body 11 can be reduced by filling the notch unit 111a or removing the stepped structure 112. That is, the minimum size of the block-shaped notch 111 is increased by reducing the number of stepped structures. For example, the side length of the notch unit 111a of the original target pattern in FIG. 6 is the minimum size of the block-shaped notch 111. After the processing, the minimum size of the recessed block-shaped notch of the secondary target pattern 13 is three times the side length of the notch unit 111a, thereby increasing the minimum size of the block-shaped notch of the secondary target pattern 13. In this way, the simulated contour 12 is closer to the original target pattern, thereby increasing the correction accuracy.

In some embodiments, with reference to FIG. 6, the original target pattern includes 2 notch units 111a; the notch unit 111a corresponding to one of the stepped structures 112 is filled and another stepped structure 112 is removed to form a secondary target pattern 13. Compared with the original target pattern and the secondary target pattern 13, the number of steps of the stepped structure 112 is reduced, and the minimum size of the block-shaped notch becomes larger, so that the simulated contour 12 acquired from the secondary target pattern 13 is closer to the original target pattern, thereby increasing the accuracy of correction.

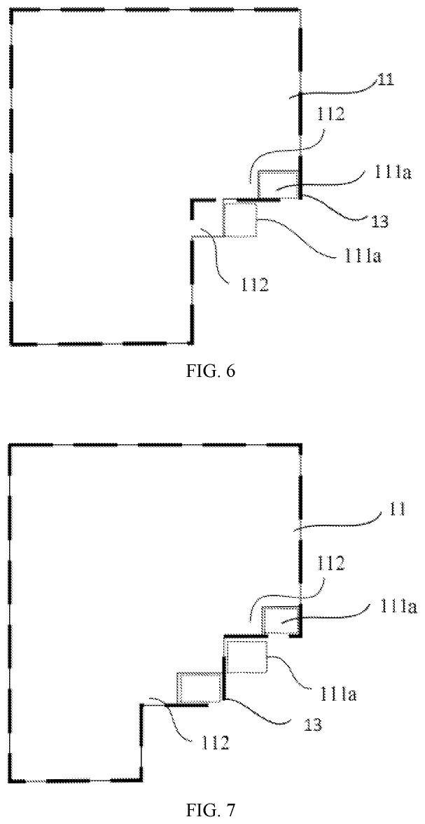

In some embodiments, with reference to FIG. 7, which is a structural diagram of a comparison between another original target pattern and a secondary target pattern according to an embodiment of the present disclosure, the original target pattern includes 3 notch units 111a; the notch units 111a corresponding to two stepped structures 112 in proximity to the main body 11 are filled to form the secondary target pattern 13. Compared with the original target pattern and the secondary target pattern 13, the number of steps of the stepped structure 112 is reduced from three to one, and the minimum size of the block-shaped notch is twice the side length of the notch unit 111a. In this way, the simulated contour 12 acquired from the secondary target pattern 13 is closer to the original target pattern, which increases the accuracy of correction.

In step S220, a secondary target pattern is processed with an optical proximity effect correction to acquire a corrected pattern.

In step S230, a simulated contour of the original target pattern is acquired based on the corrected pattern.

In step S240, a value of the deviation between the simulated contour and the original target pattern is calculated, and whether the corrected pattern meets the processing requirements is judged based on the deviation value.

In the present embodiment, the original target pattern is preprocessed. That is, the recessed block-shaped notch in the main body in the original target pattern is filled to form the secondary target pattern, and the secondary target pattern, rather than the original target pattern, is used as an operation object of the optical proximity effect correction, so that the deviation rate of the acquired simulated contour is small, which is beneficial to shorten the cycle of the optical proximity effect, improves the accuracy of the resulting mask pattern, and increases the production yield of the device.

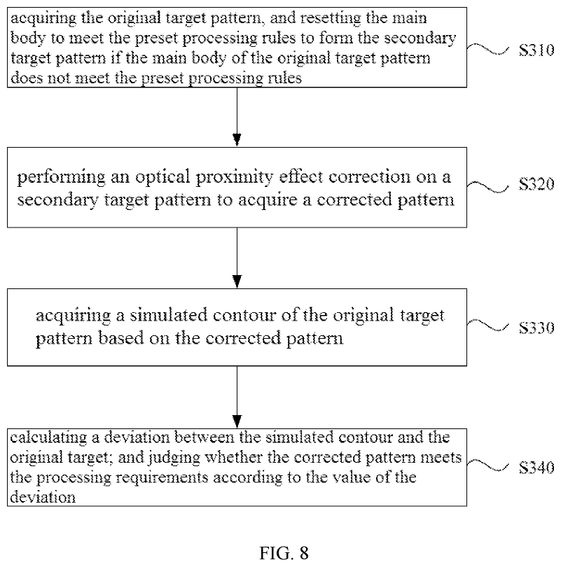

In some embodiments, the preset processing rules include at least one of the following: the width of the line is greater than or equal to a width threshold; the width of the separation between adjacent lines is greater than or equal to a separation threshold; and a distance between a centerline of the line and a centerline of the adjacent separation is greater than or equal to a spacing threshold. Accordingly, in the embodiments of the present disclosure, the preprocessing process of the original target pattern is specifically limited. As shown in FIG. 8, which is a flowchart of another method for optical proximity effect correction according to an embodiment of the present disclosure, the method for optical proximity effect correction may include the following steps.

In S310, the original target pattern is acquired. If the main body of the original target pattern does not meet the preset processing rules, the main body is reset to meet the preset processing rules to form the secondary target pattern.

In the present embodiment, the original target pattern is preprocessed to form a secondary target pattern. The specific process is to judge and test the preset processing rules one by one, screen out the cases that do not meet the preset process rules, and reset the target pattern to form a secondary target pattern.

In the present embodiment, the dimensions of the lines and settings of the original target pattern are set to reduce the distortion of the final simulated contour. It is exemplarily shown in FIG. 9 which is a structural diagram of yet another original target pattern according to an embodiment of the present disclosure. If the distance between the ends of two lines 112 in FIG. 9 is too small, the formed simulated contour 12 after the original target pattern is corrected by the optical proximity effect correction model is prone to connected lines, which causes errors in the mask image.

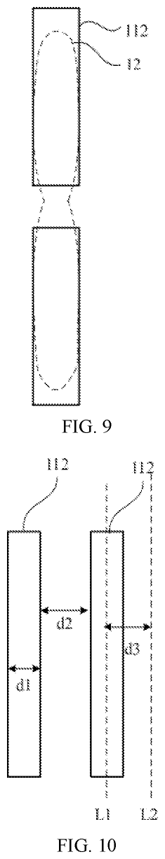

Preset processing rules are set in the present embodiment. The preset processing rules may include at least one of the following items. In some embodiments, it is shown in FIG. 10, which is a structural diagram of lines in a target pattern according to an embodiment of the present disclosure. If the target pattern includes multiple parallel lines 112, a width d1 of the line can be limited to be greater than or equal to the width threshold, a width d2 of a separation between the adjacent lines 112 can be limited to be greater than or equal to the separation threshold, and a distance d3 between a centerline L1 of the line 112 and the centerline L2 of an adjacent separation can be limited to be greater than or equal to the spacing threshold. Thus, the interaction between adjacent lines 112 is prevented so that the simulated contour is prone to distortion. Therefore, if the original target pattern cannot meet at least one of the aforementioned preset processing rules, the width and position of the line 112 of the target pattern are adjusted again to form a secondary target pattern that meets the aforementioned preset processing rules.

In some embodiments, the width threshold may be 50 nm, the separation threshold may be 100 nm; and the spacing threshold may be 200 nm. When the width d1 of the line 112 is greater than or equal to 50 nm, the width d2 of the separation between adjacent lines 112 is greater than or equal to 100 nm, and the distance d3 between the centerline L1 of the line 112 and the centerline L2 of the adjacent separation is greater than or equal to 200 nm, there exists less interaction between adjacent lines, whereby the optical proximity effect correction model exhibits an improved rate of correction, the correction cycle is shortened, and the accuracy of the final photo-etched pattern is improved.

In step S320, an optical proximity effect correction is performed on a secondary target pattern to acquire a corrected pattern.

In step S330, a simulated contour of the original target pattern is acquired based on the

In step S340, a value of the deviation between the simulated contour and the original target is calculated, and whether the corrected pattern meets the processing requirements is determined according to the value of the deviation.

In the present embodiment, the dimensions and positions of the lines in the original target pattern are set to form the secondary target pattern so that the secondary target pattern meets the preset processing rules. The secondary target pattern is used as a correction object of the optical proximity effect model so as to avoid distortion and error caused by correction directly performed on the original object pattern, thereby improving the efficiency of the optical proximity correction process.

The above steps S210 to S240 and steps S310 to S340 are settings in dimensions and positions specific to the exposed pattern. In some embodiments, the original target pattern further includes optical auxiliary lines. The present process rule may include any one of the following: for two optical auxiliary lines whose extending directions are perpendicular to each other, a separation between a side edge of a first optical auxiliary line and an end of a second optical auxiliary line is greater than or equal to a first auxiliary separation threshold; a width of the first optical auxiliary line is greater than or equal to a first auxiliary width threshold; a width of the optical auxiliary line arranged in a separation between two main bodies is less than or equal to a second auxiliary width threshold; and the separation between the optical auxiliary line close to the virtual pattern and the virtual pattern is greater than or equal to a second auxiliary separation threshold.

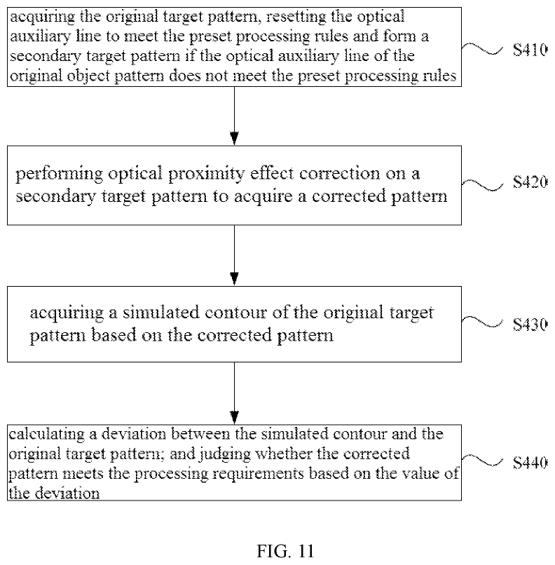

Accordingly, a pre-processing process on the original target pattern is described in the disclosed embodiment. As shown in FIG. 11, which is a flowchart of another method for optical proximity effect correction according to an embodiment of the present disclosure, the method for optical proximity effect correction may include the following steps.

In step S410, the original target pattern is acquired. If the optical auxiliary line of the original object pattern does not meet the preset processing rules, the optical auxiliary line is reset to meet the preset processing rules and form a secondary target pattern.

The original target pattern includes not only a target pattern which is used for forming a photo-etched pattern but also an optical auxiliary line for assisting the photo-etched pattern to enhance the process window. The width of the optical auxiliary line is small and will not affect the exposed pattern after the exposure. That is, the optical auxiliary line will not form a simulated contour. However, either the dimension of the optical auxiliary line being too larger or the position being set too near will easily cause a distortion of the simulated contour and even form an exposed pattern in a direct manner.

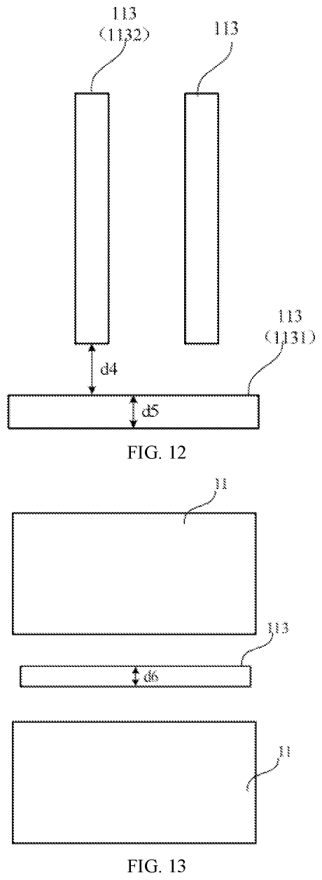

In the present embodiment, the preset processing rules may include at least one of the following items. In some embodiments, it is as shown in FIG. 12, which is a structural diagram of an optical auxiliary line according to an embodiment of the present disclosure. For two optical auxiliary lines 113 whose extending directions are perpendicular to each other, a separation d4 between a side edge of a first optical auxiliary line 1131 and an end of a second optical auxiliary line 1132 is greater than or equal to a first auxiliary separation threshold; a width d5 of the first optical auxiliary line 1131 is larger than or equal to a first auxiliary width threshold. As shown in FIG. 13, which is a structural diagram of yet another optical auxiliary line according to an embodiment of the present disclosure, a width d6 of the optical auxiliary line arranged in the separation between two main bodies is less than or equal to a second auxiliary width threshold.

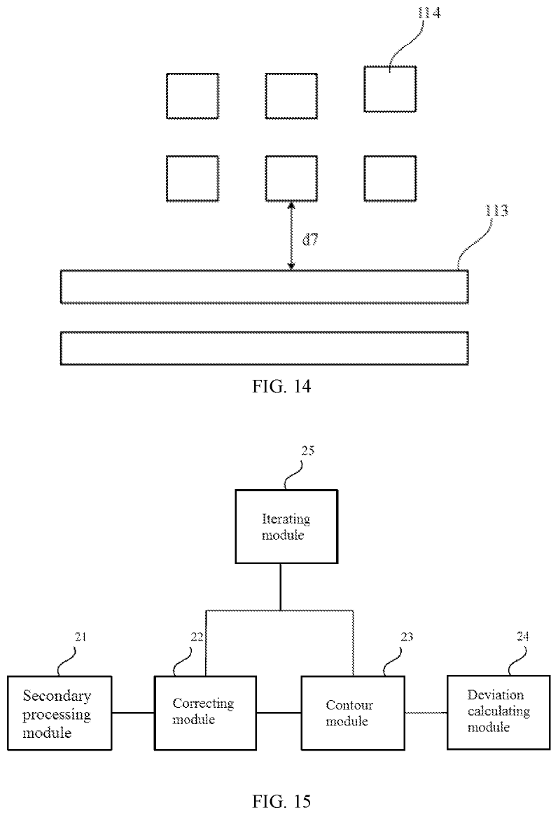

Further, as shown in FIG. 14, which is a structural diagram of yet another optical auxiliary line according to an embodiment of the present disclosure, a separation d7 between an optical auxiliary line 113 close to the virtual pattern 114 and the virtual pattern 114 is greater than or equal to a second auxiliary separation threshold. In the present embodiment, the optical auxiliary line of the original target pattern is judged according to the aforementioned preset processing rules, and the optical auxiliary line which does not meet the aforementioned preset processing rules is reset to form a secondary target pattern.

In some embodiments, a first auxiliary separation threshold is 20 nm, a first auxiliary width threshold is 10 nm, a second auxiliary width threshold is 40 nm, and a second auxiliary separation threshold is 200 nm. When the separation d4 between a first optical auxiliary line 1131 and a second optical auxiliary line 1132 which are perpendicular to each other is larger than or equal to 20 nm, a width d5 of a first optical auxiliary line 1131 is larger than or equal to 10 nm, a width d6 of the optical auxiliary line 113 in a separation between two main bodies 11 is less than or equal to 40 nm, and a separation d7 between the optical auxiliary line 113 and the virtual pattern 114 is larger than or equal to 200 nm, the optical auxiliary line will neither affect the exposed pattern nor cause a distortion in a simulated contour.

In step S420, the optical proximity effect correction is performed on a secondary target pattern to acquire a corrected pattern.

In step S430, a simulated contour of the original target pattern is acquired based on the corrected pattern.

In step S440, a value of the deviation between the simulated contour and the original target pattern is calculated, and whether the corrected pattern meets the processing requirements is judged based on the deviation value.

In the present embodiment, the dimension and position of the optical auxiliary line which does not form an exposed pattern in the original exposed pattern are set to form the secondary target pattern, thus improving an efficiency of the optical proximity effect correction and improving the accuracy of the correction.

On the basis of the aforementioned embodiments, the preset processing rules in the present embodiment may meet all definite preset processing rules mentioned in steps S210, S310 and S410 to improve the accuracy of corrected pattern obtained after the secondary target pattern is corrected through the optical proximity correction model, which improves accuracy of optical proximity correction, effectively reduces the number of calling the optical proximity correction model, and reduces the cycle of the optical proximity effect correction. A better correction effect can be achieved, and the qualification rate of the final product can be improved.

Based on the same conception, the disclosed embodiment provides a device for optical proximity correction, which is configured to implement the optical proximity correction provided by any embodiment of the present disclosure. FIG. 15 is a structural diagram of a device for optical proximity effect correction according to an embodiment of the present disclosure. As shown in FIG. 15, the device for optical proximity effect correction may include the following modules:

a secondary processing module 21, configured to acquire an original target pattern and preprocess the original target pattern to form a secondary target pattern so that the secondary target pattern meets preset processing rules;

a correcting module 22, configured to perform optical proximity effect correction on the secondary target pattern to acquire a corrected pattern;

a contour module 23, configured to acquire a simulated contour of the original target pattern based on the corrected pattern;

a deviation calculation module 24, configured to simulate a deviation between the simulated contour and the original target pattern; and

an iterative module 25, configured to recursively call the correction module and the contour module until the value of deviation acquired by the deviation calculating module meets the processing requirements.

In the present embodiment, prior to the optical proximity effect correction is performed on the target pattern, the original target pattern is preprocessed. To be specific, the original target pattern that will affect the accuracy of the exposed pattern finally exposed on the film layer is corrected and adjusted in advance to form the second target pattern. That is, the original target pattern that does not meet the preset processing rules is adjusted to form the second target pattern that meets the preset processing rules, the optical proximity effect correction is performed on the secondary target pattern to acquire a corrected pattern, and an exposure process is simulated on the corrected pattern to acquire a simulated contour. The simulated contour is compared with the original target pattern and may be determined as the accurate final corrected pattern if the deviation value meets the processing requirements, and an exposed pattern which is close to the original target pattern is acquired based on the corrected pattern. Compared with direct optical proximity effect correction on the original target pattern, processing the original target pattern in advance eliminates factors of pattern which cause deformation to the final simulated contour, ensures that the simulated contour may overlay the original target pattern, prevents serious distortion of the exposed pattern, improves the performance of the device which is formed finally, and increases the yield of production.

It shall be noted that the aforementioned are merely preferred embodiments and applied technical principles of the present disclosure. It is understood by the skilled in the art that the present disclosure is not limited to the specific embodiments. Those skilled in the art may make various obvious changes, readjustments and substitutions without departing from the scope of protection of the present disclosure. As a result, although the present disclosure has been described in more detail through the above embodiments, the present disclosure is not limited to the above embodiments, and can further include more other equivalent embodiments without departing from the concept of the present disclosure, and the scope of the present disclosure is determined by the scope of the appended claims.

What is claimed is:

1. A method for optical proximity effect correction, comprising:
acquiring an original target pattern and preprocessing the original target pattern to form a secondary target pattern so that the secondary target pattern meets a preset processing rule;
performing optical proximity effect correction on the secondary target pattern to acquire a corrected pattern;
acquiring a simulated contour of the original target pattern based on the corrected pattern;
calculating a deviation between the simulated contour and the original target pattern; and
judging whether the corrected pattern meets processing requirements based on a value of the deviation.

2. The method for optical proximity effect correction according to claim 1, wherein the preset processing rule comprises: a main body doesn't comprise a recessed block-shaped notch; and preprocessing the original target pattern to form the secondary target pattern comprises:
based on that the original target pattern comprises the recessed block-shaped notch on the main body, the second target pattern is formed by extending along a contour line of the main body so that the recessed block-shaped notch on the main body is filled.

3. The method for optical proximity effect correction according to claim 2, wherein based on that the original target pattern comprises the recessed block-shaped notch on the main body, the second target pattern is formed by extending along the contour line of the main body so that the recessed block-shaped notch on the main body is filled, comprising:
based on that the original target pattern comprises the recessed block-shaped notch formed on a corner area of two contour lines perpendicular with each other of the main body, the corner area is filled along the contour lines of the main body to form a right-angle area, thereby forming the secondary target pattern.

4. The method for optical proximity effect correction according to claim 2, wherein a minimum size of the block-shaped notch is less than or equal to 10 nm.

5. The method for optical proximity effect correction according to claim 2, wherein the recessed block-shaped notch comprises multiple notch units arranged in stepped manner; the notch unit corresponds to a stepped structure on the main body in a one-to-one relationship;
based on that the original target pattern comprises the recessed block-shaped notch on the main body, the second target pattern is formed by extending along the contour line of the main body so that the recessed block-shaped notch on the main body is filled, comprises:
based on that the block-shaped notch of the original target pattern comprises the multiple notch units arranged in the stepped manner, the notch unit is filled and/or the stepped structure corresponding to the notch unit is removed to form the secondary target pattern so that the minimum size of the recessed block-shaped notch on the main body is larger than 10 nm.

6. The method for optical proximity effect correction according to claim 5, wherein the number of notch units included in the original target pattern is 2, one of the notch units is filled, and the stepped structure corresponding to the other notch unit is removed to form the secondary target pattern.

7. The method for optical proximity effect correction according to claim 5, wherein the number of notch units included in the original target pattern is 3, notch units corresponding to the two stepped structures close to the main body are filled to form the secondary target pattern.

8. The method for optical proximity effect correction according to claim 1, wherein the preset processing rules comprises at least one of:
a width of the line is greater than or equal to a width threshold;
a width of a separation between adjacent lines is greater than or equal to a separation threshold; and
a distance between a centerline of the line and a centerline of an adjacent separation is greater than or equal to a spacing threshold;
wherein preprocessing the original target pattern to form the secondary target pattern comprises:
in response to a fact that the main body of the original target pattern does not meet the preset processing rule, the main body is reset to meet the preset processing rule to form the secondary target pattern.

9. The method for optical proximity effect correction according to claim 1, wherein the original target pattern comprises an optical auxiliary line, the optical auxiliary line comprising a first optical auxiliary line and a second optical auxiliary line whose extending directions are perpendicular; and the preset processing rule comprises any one of:
a separation between a side edge of the first optical auxiliary line and an end of the second optical auxiliary line is greater than or equal to a first auxiliary separation threshold;
a width of the first optical auxiliary line is greater than or equal to a first auxiliary width threshold;
a width of the optical auxiliary line arranged in the separation between two main bodies is less than or equal to a second auxiliary width threshold; and
a separation between the optical auxiliary line close to an imaginary pattern and the imaginary pattern is greater than or equal to a second auxiliary separation threshold; and
wherein preprocessing the original target pattern to form the secondary target pattern comprises:
in response to a fact that the optical auxiliary line of the original target pattern does not meet the preset processing rule, the optical auxiliary line of the original target pattern is reset to meet the preset processing rule to form the secondary target pattern.

10. The method for optical proximity effect correction according to claim 9, wherein the first auxiliary separation threshold is 20 nm, the first auxiliary width threshold is 10 nm, the second auxiliary width threshold is 40 nm, and the second auxiliary separation threshold is 200 nm.

11. The method for optical proximity effect correction according to claim 1, further comprising:
performing optical proximity effect correction on the secondary target pattern multiple times until the acquired deviation value between the simulated contour and the original target pattern meets the processing requirements.

12. A device for optical proximity effect correction, wherein the device is used for implementing a method for optical proximity effect correction according to claim 1, the device comprising:
a secondary processing module, configured to acquire an original target pattern and preprocess the original target pattern to form a secondary target pattern such that the secondary target pattern meets a preset processing rule;
a correcting module, configured to perform optical proximity effect correction on the secondary target pattern to acquire a corrected pattern;
a contour module, configured to acquire a simulated contour of the original target pattern based on the corrected pattern;
a deviation calculating module, configured to calculate a deviation between the simulated contour and the original target pattern; and
an iterating module, configured to call the correcting module and the contour module in a cyclical manner until a value of the deviation acquired by the deviation calculating module meets processing requirements.
